(19) United States
(12) Patent Application Publication
(10) Pub. No.: US 2006/0146382 A1
(43) Pub. Date: Jul. 6, 2006

(54) Color image forming apparatus and image storing device

(75) Inventor: Kazuyoshi Tanaka, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Konica Minolta Business Technologies, Inc., Tokyo (JP)

(21) Appl. No.: 11/101,128

(22) Filed: Apr. 7, 2005

(30) Foreign Application Priority Data
Jan. 6, 2005 (JP) JP2005-001531

(51) Int. Cl. G03F 3/08

(52) U.S. Cl. 358/518; 358/1.9

(57) ABSTRACT

In an image storing device for use in a color image forming apparatus for storing dispersively image data of each color constituting a color image in the plurality of image storing devices each taking charge of at least one color, reading image data of a charging color from each image storing device, and forming the color image, the image storing device has an area for storing image data of each color for a color image to be stored beforehand, for all colors constituting the color image.

This application is based on Japanese Patent Application No. 2005-001531 filed on Jan. 6, 2005 in Japanese Patent Office, the entire content of which is hereby incorporated by reference.

### BACKGROUND OF THE INVENTION

The present invention relates to a color image forming apparatus for storing dispersively image data of each color forming a color image in a plurality of image storing devices respectively taking charge of one or more colors, a image storing device thereof and a manufacturing method of an image storing device.

A color image forming apparatus such as a copier generally realizes a full-color using four colors of yellow (Y), magenta (M), cyan (C), and black (K) and inside the apparatus, the four colors are controlled by image data of each color. Further, to temporarily store an image, a large capacity magnetic disk unit is used. However, to realize high-speed input and output, four magnetic disk units by color are prepared and are operated in parallel, thus the four colors are processed simultaneously. By use of this constitution, compared with a case that image data by color are sequentially stored in one magnetic disk unit, a processing speed of practically four times is ensured.

On the other hand, some copier has a stamp function for adding a stamp image such as “Strict Secrecy” or “Confidential” to a read document image and copying it and to realize this function, in a magnetic disk unit of an image forming apparatus, image data of an stamp image (hereinafter, referred to as “stamp data”) is initially loaded at the time of shipment. In a color copier, a color-full stamp image such as the rainbow color is set and in a magnetic disk unit of each color, stamp data of its charging color is loaded initially.

Patent Document 1: Japanese Patent Application 2001-100929.

The magnetic disk unit is a mechanical part, which breaks down. Further, the life span thereof is generally shorter than that of the image forming apparatus, so that when the image forming apparatus is in use, a case that the magnetic disk unit must be exchanged occurs. Therefore, for the machine type having the stamp function, magnetic disk units for exchange having initially loaded stamp data are prepared at a parts center.

However, in the color image forming apparatus, in each magnetic disk unit, stamp data of its charging color must be loaded initially, so that the parts center must prepare magnetic disk units for exchange for each color. For example, when a magnetic disk unit of yellow breaks down, an exclusive magnetic disk unit of yellow in which only yellow stamp data is initially loaded for exchange must be provided from the parts center and a problem arises that the labor and cost of parts control are increased.

### SUMMARY OF THE INVENTION

The present invention was developed to solve the aforementioned problem.

An image storing devices for use in a color image forming apparatus for storing dispersively image data of each color constituting a color image in a plurality of image storing devices each taking charge of at least one color, reading image data of a charging color from each image storing device, and forming the color image, the image storing device comprising: an area for storing image data of each color for a color image to be stored beforehand, for all colors constituting the color image.

A color image forming apparatus for storing dispersively image data of each color constituting a color image in a plurality of image storing devices each taking charge of at least one color, reading image data of a charging color from each image storing device, and forming the color image, wherein when any of the plurality of image storing devices is replaced with the image storing device described in claim 1, image data of each color for a color image stored therein beforehand is copied to at least one of the image storing devices which have not been replaced.

A color image forming apparatus comprising: (a) a plurality of image storing devices each for storing at least one of image data of each color constituting a color image; (b) a controller for controlling so as to read the image data of each color in parallel from the image storing devices; and (c) image forming units for forming a color image, on the basis of the image data of each color read in parallel from the image storing devices, wherein the plurality of image storing devices store the image data for a color image to be stored beforehand, for all colors constituting the color image to be stored beforehand.

A method for manufacturing an image storing device for use in a color image forming apparatus for stroing dispersively image data of each color constituting a color image in a plurality of image storing devices each taking charge of at least one color, reading image data of a charging color from each image storing device, and forming the color image, comprising the step of: storing image data of each color for a color image to be stored beforehand, for all colors constituting the color image to be stored beforehand.

### BRIEF DESCRIPTION OF THE DRAWINGS

FIG. 1 is an illustration showing an example of stored contents of the replacement magnetic disk unit relating to the embodiment of the present invention.

FIG. 2 is a cross sectional view showing the schematic constitution of the image forming apparatus relating to the embodiment of the present invention.

FIG. 3 is a block diagram showing the electric constitution of the color image forming apparatus relating to the embodiment of the present invention.

FIG. 4 is a flow chart showing the replacement inspection process performed by the color image forming apparatus relating to the embodiment of the present invention during the initial process when the power source is turned on.

### DETAILED DESCRIPTION OF THE PREFERRED EMBODIMENT

Hereinafter, the embodiment of the present invention will be explained with reference to the accompanying drawings.

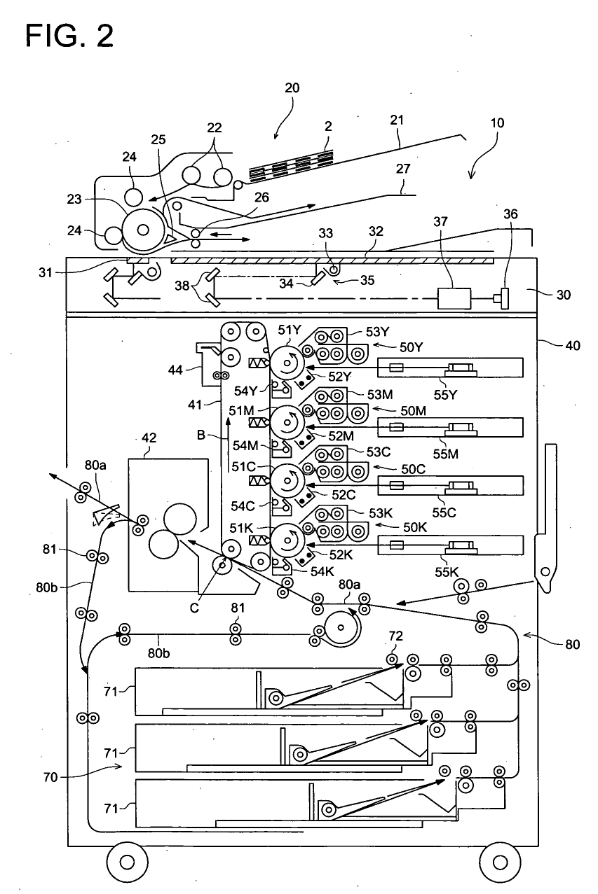

FIG. 2 is a cross sectional view showing the schematic constitution of a color image forming apparatus 10 relating to the embodiment of the present invention. The color image forming apparatus 10 is an apparatus referred to as a color digital copier having a function for reading a document image in color, forming a copied color image thereof on a sheet of paper and outputting it.

The color image forming apparatus 10 has an automatic document feeder 20, a reading section 30, and a printer section 40. The automatic document feeder 20 fulfills a function for feeding documents 2 loaded on a document tray 21 to the reading location of the reading section 30 one by one, and ejecting the read document to a paper ejection tray 27. Further, the apparatus has a function, for a double-sided document, for reading one side thereof, then turning it over, and feeding it again to the reading section 30.

The automatic document feeder 20 includes paper supply rollers 22 for sequentially feeding documents stacked on the document tray 21 sequentially from the uppermost part thereof, an contact roller 23 for passing a document in close contact with contact glass 31 which is a document reading location, and a guide roller 24 for guiding the document fed by the paper supply rollers 22 along the contact roller 23. Further, the feeder includes a switching pawl 25 for switching the moving direction of the document passing through the contact glass 31, inversion rollers 26 for inverting a double-sided document, and the paper ejection tray 27 for ejecting the read document.

The reading section 30 has a function for reading a document in color. In detail, the function divides a document into three colors such as red (R), green (G), and blue (B), optically reads them, and outputs image data of each color in which the three colors are converted to density data of four colors of yellow (Y), magenta (M), cyan (C), and black (K).

The reading section 30 includes an exposure scanning unit 35 composed of a light source 33 and a mirror 34, a line image sensor 36 of a color type for receiving reflected light from a document and outputting an electric signal of each color according to the light intensity thereof, a focusing lens 37 for focusing the reflected light from the document to the line image sensor 36, and various mirrors 38 for forming optical paths for introducing reflected light from the mirror 34 of the exposure scanning unit 35 to the line image sensor 36.

When reading a document fed by the automatic document feeder 20, the exposure scanning unit 35 moves and stops at the reading location under the contact glass 31 and reads the document conveyed and moved thereon by the contact roller 23. When reading a document loaded on a platen glass 32, the exposure scanning unit 36 moves from left to right along the bottom of the platen glass 32 and reads the document in the stopped state.

The printer section 40 is a color printer of a tandem method using the electrophotographic method. The printer section 40 includes an endless intermediate transfer belt 41, a plurality of image forming units 50Y, 50M, 50C, and 50K for respectively forming single-color images on the intermediate transfer belt 41, a paper supply portion 70 for supplying transfer paper, a conveyor unit 80 for conveying supplied transfer paper, and a fixing device 42.

The image forming unit 50Y forms a yellow (Y) image on the intermediate transfer belt 41 and the image forming unit 50M forms a magenta (M) image on the intermediate transfer belt 41. The image forming unit 50C forms a cyan (C) image on the intermediate transfer belt 41 and the image forming unit 50K forms a black (K) image on the intermediate transfer belt 41.

The image forming unit 50Y includes a cylindrical photosensitive drum 51Y for forming an electrostatic latent image, a main charger 52Y arranged around it, a developing device 53Y, and a cleaning device 54Y. Further, the image forming unit 50Y includes a laser unit 55Y composed of a laser diode, a polygonal mirror, and various lenses and mirrors.

The photosensitive drum 51Y is driven and rotated by a driving unit not illustrated in a fixed direction (the direction of an arrow A shown in the drawing) and the main charger 52Y uniformly charges the photosensitive drum 51Y. The laser unit 55Y irradiates a laser beam turned on or off according to the yellow image data and forms an electrostatic latent image on the photosensitive drum 51Y. The developing device 50Y visualizes the electrostatic latent image by yellow toner and the toner image is transferred to the intermediate transfer belt 41 at the contact location with the intermediate transfer belt 41. The cleaning device 54Y fulfills a function for rubbing, removing, and collecting toner remaining on the surface of the photosensitive drum 51Y after transfer by a blade.

The image forming units 50M, 50C, and 50K have the same constitution as that of the image forming unit 50Y except that the toner colors are different and by image data corresponding to the respective colors, the laser beam is turned on or off, thus the respective explanation will be omitted. Further, to the same components, the same numeric characters are assigned and the suffix character Y is replaced with M, C, or K.

The intermediate transfer belt 41 is supported rotatably by rotating a plurality of rollers. The intermediate transfer belt 41 is rotated round by a driving means not illustrated in the direction of an arrow B. In the round rotation process, on the intermediate transfer belt 41, images of respective colors are superimposed in order of (Y), (M), (C), and (K) by the image forming units 50Y, 50M, 50C, and 50K and a color image is composed. The color image, at a secondary transfer location C installed at the lower end of the round rotation path of the intermediate transfer belt 41, is transferred to transfer paper from the intermediate transfer belt 41. Toner remained on the intermediate transfer belt 41 after transfer is removed by a cleaning device 44.

The paper supply portion 70 feeds transfer sheets of paper stored in respective paper supply cassettes 71 toward the conveyor unit 80 one by one from the uppermost part thereof by the first paper supply roller 72. The conveyor unit 80 is composed of a general path 80a for ejecting the transfer sheets of paper sent from the paper supply cassettes 71, after passing through the secondary transfer location C and the fixing device 42, to an external exit tray and a reversal path 80b for reversing the display of the transfer sheets of paper passing through the fixing device 42 and then joining them again to the general path 80a on the upstream side of the secondary transfer location C. The respective paths 80a and 80b have many conveying rollers 81 at shorter intervals than the size of transfer paper of a minimum size in the feed direction.

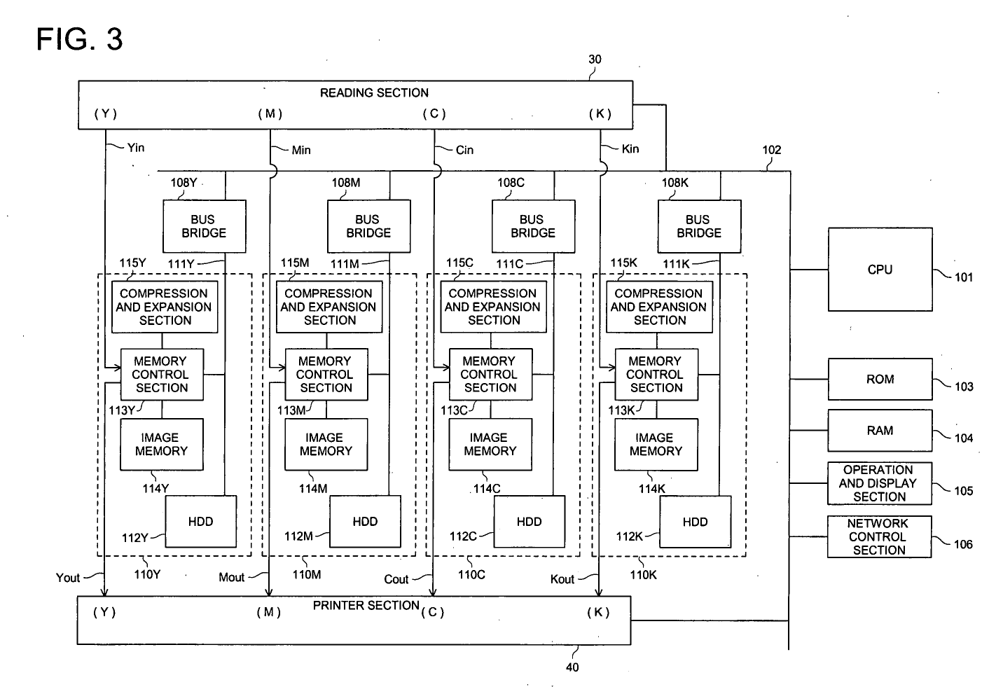

FIG. 3 shows an electric schematic constitution of the color image forming apparatus 10. The color image forming apparatus 10 has a CPU (central processing unit) 101 for generalizing and controlling the operation of the concerned devices. To the CPU 101, via a system bus 102, in addition to the reading section 30 and the printer section 40, a ROM (read only memory) 103, a RAM (random access memory) 104, an operation and display section 105, a network control section 106, and image blocks 110Y, 110M, 110C, and 110K taking charge of yellow, magenta, cyan, and black by color via bus bridges 108Y, 108M, 108C, and 108K are connected.

The ROM 103 stores various programs executed by the system bus 102 and fixed data. The RAM 104 is used as a work memory of the CPU 101. The operation and display section 105 has a function for displaying various guides and states to a user and receiving various operations from the user. The operation and display section 105 is composed of, for example, a liquid crystal display having a touch panel on its surface, various operation switches, and an operation section control CPU for controlling them.

The network control section 106 is a circuit for transferring various data with an external computer via a network such as a LAN (local area network).

The image blocks 110Y, 110M, 110C, and 110K are circuit blocks for handling image data for each color, and the image block 110Y takes charge of yellow image data, the image block 110M magenta image data, the image block 110C cyan image data, and the image block 110K black image data.

The image block 110Y has an image bus 111Y connected to the downstream side of a corresponding bus bridge 108Y and to it, a magnetic disk unit 112Y for storing image data and a memory control section 113Y are connected. To the memory control section 113Y, an image memory 114Y and a compression and expansion section 115Y are connected.

To the memory control section 113Y, yellow image data Yin inputted from the reading section 30 is input. The memory control section 113Y has a function for compressing it by the compression and expansion section 115Y and then writing it into the image memory 114Y. Further, the memory control section 113Y has a function for expanding compressed yellow image data stored in the image memory 114Y by the compression and expansion section 115Y and re-storing it in the image memory 114Y. sequentially reading the expanded yellow image data, and outputting it to the yellow laser unit 55Y of the printer section 40.

Furthermore, the image memory 114Y, at the access request from the image bus 111Y, fulfills a function for writing image data on the image bus 111Y into the image memory 114Y and a function for outputting the image data read from the image memory 114Y to the image bus 111Y.

The image blocks 110M, 110C, and 110K have the same constitution as that of the image block 110Y except that the colors of image data handled by them are different and operate similarly, so that here, detailed explanation will be omitted. Further, to the same components as those of the image block 110Y, the same numeric characters whose suffix character Y is replaced with M, C, or K are assigned.

Magnetic disk units 112Y, 112M, 112C, and 112K of respective colors have respectively a user area and a stamp area. The user area is a memory area for storing image data which is read and obtained from the reading section 30 by a user. For example, when an instruction to store image data read and obtained by the reading section 30 in the magnetic disk units is input from the user, among the image data read and obtained by the reading section 30, yellow image data is stored in the image memory 114Y, then is compressed, and is stored in the user area of the magnetic disk unit 112Y for storing yellow image data. Similarly, magenta image data is stored in the user area of the magnetic disk unit 112M, cyan image data in the user area of the cyan disk unit 112C, and black image data in the user area of the black disk unit 112K.

Further, when an instruction to form an image on the basis of the image data stored in the magnetic disk units is input from the user, the instructed image data are read in parallel from the magnetic disk units 112Y, 112M, 112C, and 112K. And, the read image data of each color is stored once in the image memories 114Y, 114M, 114C, and 114K, and then as described above, is expanded in parallel by the compression and expansion sections 115Y, 115M, 115C, and 115K, is re-stored in the respective image memories, and then is output to the laser unit of the printer section, thus an image is formed. The stamp area is a memory area for storing an image to be overlaid with another image such as “Strict Secrecy” or “Confidential”. Here, to overlay an image A with an image B is to form an image such as an image C after overlaid which is the OR of the image A and image B and as an overlay method, for example, there is a method for ORing the image data of the image A with the image data of the image B. Further, an image to be overlaid with another image, for example, is a stamp mark or a water mark. Hereinafter, an image to be overlaid will be explained as a stamp image. With respect to a specified stamp image, the stamp data thereof is stored beforehand in the magnetic disk units 112Y, 112M, 112C, and 112K when the color image forming apparatus 10 is purchased. In each stamp area of the magnetic disk units 112Y, 112M, 112C, and 112K of respective colors, at least the stamp data of its charging color is stored.

Further, the color image forming apparatus 10, when any of the magnetic disk units 112Y, 112M, 112C, and 112K fails, is structured so as to exchange the failed unit with a new one.

Next, the operation of the color image forming apparatus 10 will be explained.

Copying of a document is realized by combining an image input operation of reading a document image and compressing and storing it in the image memories 114Y, 114M, 114C, and 114K and an image output operation of expanding the image data compressed and stored in the image memories 114Y, 114M, 114C, and 114K and printing it by the printer section 40. In the image input operation, according to the document scanning operation, from the reading section 30, yellow image data Yin, magenta image data Min, cyan image data Cin, and black image data Kin are simultaneously output in parallel and are input to the image blocks 110Y, 110M, 110C, and 110K.

The image blocks 110Y, 110M, 110C, and 110K compress sequentially the image data respectively inputted to them and store them in the image memories 114Y, 114M, 114C, and 114K.

In the image output operation, the image blocks 110Y, 110M, 110C, and 110K expand the image data stored in the image memories 114Y, 114M, 114C, and 114K by the compression and expansion sections 115Y, 115M, 115C, and 115K and then store them again in the image memories 114Y, 114M, 114C, and 114K. Thereafter, according to a predetermined timing signal supplied from the printer section 40, from the image memories 114Y, 114M, 114C, and 114K, the image blocks sequentially read yellow image data Yout, magenta image data Mout, cyan image data Cout, and black image data Kout and simultaneously output them to the printer section 40 in parallel. The printer section 40, on the basis of the yellow image data Yout, magenta image data Mout, cyan image data Cout, and black image data Kout which are input, forms and outputs a color image onto a sheet of paper.

Further, when designation of image output of the image data stored in the magnetic disk units 112Y, 112M, 112C, and 112K is input from a user, the image data of each color forming a color image is simultaneously read from the magnetic disk units 112Y, 112M, 112C, and 112K in parallel and are stored once in the image memories 114Y, 114M, 114C, and 114K of the image blocks 110Y, 110M, 110C, and 110K. The image blocks 110Y, 110M, 110C, and 110K expand the image data stored in the image memories 114Y, 114M, 114C, and 114K by the compression and expansion sections 115Y, 115M, 115C, and 115K and then store them again in the image memories 114Y, 114M, 114C, and 114K. Thereafter, by the similar method to the aforementioned, the image blocks output simultaneously the image data of respective colors to the printer section 40 in parallel and form and output a color image onto a sheet of paper.

Further, at the time of job setting, when addition of a stamp image is designated, stamp data of respective colors relating to the designated stamp image is read individually and simultaneously from the magnetic disk units 112Y, 112M, 112C, and 112K taking charge of respective colors in parallel and is composed to a document image to be output. For example, when the stamp image is formed from yellow stamp data, magenta stamp data, cyan stamp data, and black stamp data, the yellow stamp data is read from the magnetic disk unit 112Y taking charge of yellow and the magenta stamp data is read from the magnetic disk unit 112M taking charge of magenta. Similarly, the cyan stamp data is read from the magnetic disk unit 112C taking charge of cyan and the black stamp data is read from the magnetic disk unit 112K taking charge of black.

The stamp data of respective colors read from the magnetic disk units 112Y, 112M, 112C, and 112K is stored once in the image memories 114Y, 114M, 114C, and 114K. The image blocks 110Y, 110M, 110C, and 110K expand the stamp data of respective colors stored in the image memories 114Y, 114M, 114C, and 114K by the compression and expansion sections 115Y, 115M, 115C, and 115K, then OR them with the image data of each color after expansion (image data according to the document image to be output) stored in the image memories 114Y, 114M, 114C, and 114K, and output them simultaneously to the printer section 40 in parallel.

Further, designation of addition of the stamp image can be carried out by inputting from the operation and display section 105 installed in the image forming apparatus 10. However, it can be carried out by inputting from an external computer via the network control section.

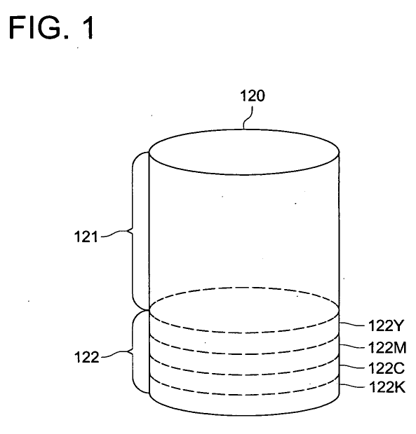

FIG. 1 shows an example of the memory area of the replacement magnetic disk unit 120. The replacement magnetic disk unit 120 has a user area 121 and a stamp area 122. In the stamp area 122, yellow stamp data 122Y, magenta stamp data 122M, cyan stamp data 122C, and black stamp data 122K are stored beforehand. Data is stored in the stamp area 122, for example, at a factory before shipment to the parts center. Stamp data by color is stored for all colors in the replacement magnetic disk unit 120 like this, so that the same replacement magnetic disk unit 120 can be shared by all colors and compared with a case that the replacement magnetic disk unit is controlled for each color, the labor and cost of parts control are greatly reduced.

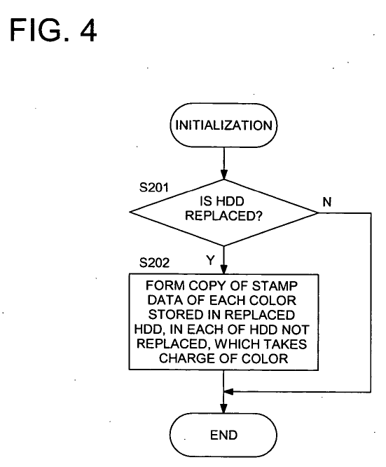

FIG. 4 shows the replacement inspection process performed by the CPU 101 of the color image forming apparatus 10 during the initial process when the power source is turned on. Further, in this embodiment, the CPU 101 fulfills the function of the detection means. Firstly, the CPU 101 inspects whether there is the magnetic disk unit 120 exchanged or not (Step S201). For example, the CPU 101 checks whether predetermined use start information is registered in a specific area of the magnetic disk unit or not, and when it is not registered, decides that it is immediately after exchange, registers the use start information, and when it is registered already, decides that it is not immediately after exchange. Further, the inspection method is not limited to it and various methods can be adopted.

When there is the magnetic disk unit 120 exchanged (Step S201: Y), the CPU 101 prepares copies of the stamp data of each color stored in the replacement magnetic disk unit 120 in the existing magnetic disk units not exchanged (Step S202). At this time, the CPU 101, in each of the magnetic disk units, copies only the stamp data of the color that the concerned magnetic disk unit takes charge of colors from the replacement magnetic disk unit 120. When there is not the magnetic disk unit 120 exchanged (Step S201: N), the CPU 101 finishes the replacement inspection process without copying stamp data (End).

After end of the replacement inspection process, the stamp data of each color registered in the replacement magnetic disk unit 120 is copied by the existing magnetic disk units taking charge of respective colors, so that in the image output operation, the general operation of reading and processing the stamp data individually and simultaneously from the magnetic disk units 112Y, 112M, 112C, and 112K taking charge of respective colors in parallel can be performed.

For example, when the magenta magnetic disk unit is replaced with the replacement magnetic disk unit 120, the yellow stamp data is copied from the replacement magnetic disk unit 120 onto the magnetic disk unit 112Y, and the cyan stamp data is copied from the replacement magnetic disk unit 120 onto the magnetic disk unit 112C, and the black stamp data is copied from the replacement magnetic disk unit 120 onto the magnetic disk unit 112K. Further, the replacement magnetic disk unit 120 may take charge of magenta, so that after completion of the aforementioned copying, it is possible to erase the yellow, cyan, and black stamp data copied on the existing magnetic disk units from the replacement magnetic disk unit 120 and use the concerned part as a user area 121.

According to the image storing device relating to the presentembodiment, for an image to be stored beforehand, image data of all colors is stored, so that one image storing device can be commonly used for exchange of an image storing device taking charge of any color, and control of each color is not required, thus the labor and cost of manufacture control of image storing devices can be reduced.

Further, in the color image forming apparatus, when an image storing device broken down is replaced with a replacement image storing device, the image data of each color stored in it beforehand is copied on the existing image storing devices, so that with respect to an image initially loaded on the replacement image forming apparatus, the image data of each color can be read from a plurality of image storing devices in parallel and can respond to a high-speed output process.

In the color image forming apparatus of this embodiment for storing dispersively image data of each color forming a color image in a plurality of image storing devices respectively taking charge of one or more colors, reading, from each image storing device, image data of its charging color, and forming a color image, when any of the plurality of image storing devices is replaced with the aforementioned image storing device, the image data of each color stored in it beforehand is copied on the existing image storing devices.

By doing this, through the replacement image storing device, a new image such as a new stamp image can be distributed. Further, image data of all colors may be copied on the existing image storing devices.

Further, in this embodiment, in the existing image storing devices, only for the respective charging colors, the image data of each color stored in the image storing device after replacement is copied, so that after copying, the image data of each color initially loaded on the replacement image storing device can be read simultaneously from a plurality of image storing devices in parallel and can respond to a high-speed output process.

The embodiment of the present invention is explained above by referring to the drawings. However, the concrete constitution is not limited to the one indicated in the embodiment and modifications and additions within a range which is not deviated from the object of the present invention are included in the present invention.

For example, in this embodiment, on an existing magnetic disk unit, only the stamp data of its charging color is copied from the replacement magnetic disk unit 120. However, the existing magnetic disk unit may be structured so as to copy stamp data of all colors on it.

Further, a device for storing an image is not limited to the magnetic disk unit and may be an image storing device of another type. However, it is preferably a nonvolatile large capacity storage for storing rewritably image data. Further, image data to be initially stored in the replacement magnetic disk unit 120 is not limited to image data overlaid with another image such as stamp data and another kind of image data is acceptable.

Further, an image forming apparatus having a loaded image storing device may use, among image data of all colors initially loaded thereon, image data of the color which the concerned replacement image storing device takes charge of. Further, image data of a color which the concerned device does not take charge of may be structured so as to be copied on another existing image storing device. Furthermore, the image forming apparatus may erase image data of an unnecessary color from the image storing device mounted and use the area as a general memory area.

What is claimed is:

1. An image storing devices for use in a color image forming apparatus for storing dispersively image data of each color constituting a color image in a plurality of image storing devices each taking charge of at least one color, reading image data of a charging color from each image storing device, and forming the color image, the image storing device comprising:
an area for storing image data of each color for a color image to be stored beforehand, for all colors constituting the color image.

2. The plurality of image storing devices of claim 1, wherein the image storing device is an image storing device for replacement.

3. The plurality of image storing devices of claim 1, wherein the color image to be stored beforehand is an image to be overlaid with another image.

4. The plurality of image storing devices of claim 1, wherein the image storing device is a magnetic disk device.

5. The plurality of image storing devices of claim 4, wherein the magnetic disk device is a hard disk device.

6. A color image forming apparatus for storing dispersively image data of each color constituting a color image in a plurality of image storing devices each taking charge of at least one color, reading image data of a charging color from each image storing device, and forming the color image, wherein when any of the plurality of image storing devices is replaced with the image storing device described in claim 1, image data of each color for a color image stored therein beforehand is copied to at least one of the image storing devices which have not been replaced.

7. The color image forming apparatus of claim 6, wherein the plurality of image storing devices are provided to correspond to each of the image data each color, the color image is formed by reading in parallel the image data from each of the plurality of image storing devices.

8. The color image forming apparatus of claim 6, wherein the image data each color stored in the image storing device which has been replaced, is copied only to each of the image storing devices taking charge of the color, which have not been replaced.

9. The color image forming apparatus of claim 6, further comprising a detector for detecting that the image storing device is replaced, wherein when the detector detects that the image storing device is replaced, data not stored in other image storing device among a color image data stored in the image storing device that has been replaced, is stored in the other image storing device.

10. The color image forming apparatus of claim 9, wherein when the detector detects that the image storing device is replaced, it is detected if there are data which are not stored in other image storing device among the color image data stored in the image storing device that has been replaced and a copy of the data not stored in other image storing device is stored in the other image storing device.

11. A color image forming apparatus comprising:
(a) a plurality of image storing devices each for storing at least one of image data of each color constituting a color image;
(b) a controller for controlling so as to read the image data of each color in parallel from the image storing devices; and
(c) image forming units for forming a color image, on the basis of the image data of each color read in parallel from the image storing devices,
wherein the plurality of image storing devices store the image data for a color image to be stored beforehand, for all colors constituting the color image to be stored beforehand.

12. The color image forming apparatus of claim 11, wherein the image storing device is an image storing device for replacement.

13. The color image forming apparatus of claim 11, wherein the color image to be stored beforehand is an image to be overlaid with another image.

14. The color image forming apparatus of claim 11, the image storing device is a magnetic disk device.

15. The color image forming apparatus of claim 14, wherein the magnetic disk device is a hard disk device.

16. A method for manufacturing an image storing device for use in a color image forming apparatus for stroing dispersively image data of each color constituting a color image in a plurality of image storing devices each taking charge of at least one color, reading image data of a charging color from each image storing device, and forming the color image, comprising the step of:
storing image data of each color for a color image to be stored beforehand, for all colors constituting the color image to be stored beforehand.

17. The method of claim 16, wherein the image storing device is an image storing device for replacement.

18. The method of claim 16, wherein the color image to be stored beforehand is an image to be overlaid with another image.

19. The method of claim 16, the image storing device is a magnetic disk device.

20. The method of claim 19, wherein the magnetic disk device is a hard disk device.
